(19) United States
(12) Patent Application Publication
(10) Pub. No.: US 2018/0180651 A1
(43) Pub. Date: Jun. 28, 2018

(54) SYSTEM AND METHOD FOR TESTING NETWORK-SIDE HARMONIC COMPONENT OF MOTOR TRAIN UNIT

(71) Applicant: CRRC QINGDAO SIFANG CO., LTD., Qingdao, Shandong (CN)

(72) Inventors: Jin YU, Qingdao, Shandong (CN); Xiaojun DENG, Qingdao, Shandong (CN); Shaoqing LIU, Qingdao, Shandong (CN); Yue XU, Qingdao, Shandong (CN); Weikai YU, Qingdao, Shandong (CN); Guanji XU, Qingdao, Shandong (CN); Zhulin HE, Qingdao, Shandong (CN); Bo ZHANG, Qingdao, Shandong (CN)

(73) Assignee: CRRC QINGDAO SIFANG CO., LTD., Qingdao, Shandong (CN)

(21) Appl. No.: 15/120,014

(22) PCT Filed: Oct. 28, 2015
(86) PCT No.: PCT/CN2015/093027

§ 371 Date: Aug. 18, 2016

(30) Foreign Application Priority Data
Nov. 17, 2014 (CN) 201410654751.5

(51) Int. Cl. G01R 23/20

(52) U.S. Cl. CPC G01R 23/20; G01R 19/0092

(57) ABSTRACT

A system and method for testing a network-side harmonic component of a motor train unit, the method comprising: detecting a current of each power unit, sampling and quantifying the detected current, acquiring a digital current signal of each power unit, superimposing each digital current to obtain a current of the entire train, and acquiring a harmonic component according to the current of the entire train. A sample frequency is determined according to a frequency and a target phase angle error of the harmonic component to be detected. The provided system and method for testing the network-side harmonic component of the motor train unit improve a detection accuracy of harmonic current and can detect the harmonic component at a frequency above 3000 Hz.

The present application claims priority to Chinese Patent Application No. 201410654751.5, titled “SYSTEM AND METHOD FOR GRID-SIDE HARMONIC TESTING OF CRH UNIT”, filed on Nov. 17, 2014 with the State Intellectual Property Office of People's Republic of China, which is incorporated herein by reference in its entirety.

### FIELD

The present disclosure relates to the technical field of testing, and in particular to a system and method for a grid-side harmonic test on a multiple-unit.

### BACKGROUND

The speed of a multiple-unit is normally adjusted in an AC-DC-AC manner, and a harmonic wave is inevitably generated on the grid-side. The harmonic wave may interfere with communication equipments in the vicinity, and affect the normal operation of a rail circuit due to a current signal flowing back through rails. In addition, the harmonic wave may cause magnetic saturation of a traction transformer, the loss is increased and the heat production is aggravated. Therefore, it is required to accurately know the harmonic wave distribution and harmonic wave content of a multiple-unit.

At present, no vehicular detecting device or technique can detect a whole train current signal effectively. The whole train current signal can only be obtained by detecting a grid-side current signal of each power unit and adding up the detected instantaneous currents. Then a harmonic component is obtained based on the whole train current.

However, it is discovered in practice that the existing harmonic current signal detecting method has a low accuracy, and it is difficult to detect a harmonic component having a frequency above 3000 Hz.

### SUMMARY

An objective of the present disclosure is to provide a system and a method for a grid-side harmonic test on a multiple-unit, in order to improve an accuracy of the grid-side harmonic test on the multiple-unit.

In order to achieve the above objective, technical solutions are provided as follows according to embodiments of the present disclosure.

A system for a grid-side harmonic test on a multiple-unit includes:

a plurality of current sensors connected to power units of the multiple-unit in a one-to-one correspondence;

a plurality of first type of collecting cards connected to the current sensors in a one-to-one correspondence, where the plurality of first type of collecting cards are configured to sample and quantify current signals detected by the current sensors, so as to convert analog current signals detected by the current sensors into digital current signals, a sampling frequency of the first type of collecting cards is greater than or equal to a predetermined threshold f_{T}=(360/Δθ)×f₀, where f_{T} denotes the predetermined threshold, Δθ denotes an error of phase angle of a harmonic component to be detected, and f₀ denotes a frequency of the harmonic component to be detected; and

a first controller connected to the plurality of first type of collecting cards, and configured to obtain a whole train current signal by adding up the digital current signals and to obtain the harmonic component based on the whole train current signal.

Preferably, in the system mentioned above, the current sensors may have an accuracy of 0.05%.

Preferably, in the system mentioned above, the first controller, which is configured to obtain the whole train current signal by adding up the digital current signals, may be configured to:

perform temperature compensation on the digital current signals and obtain the whole train current signal by adding up the digital current signals on which the temperature compensation has been performed.

Preferably, in the system mentioned above, the first controller, which is configured to obtain the whole train current signal by adding up the digital current signals on which the temperature compensation has been performed, may be configured to:

perform non-linear compensation on the current signals on which the temperature compensation has been performed, and obtain the whole train current signal by adding up the digital current signals on which the non-linear compensation has been performed, where a non-linear compensation value is predetermined with experiments.

Preferably, in the system mentioned above, the first type of collecting cards may be analog-to-digital converters having a sampling frequency greater than or equal to the predetermined threshold and a conversion accuracy of 24 bits.

Preferably, the system mentioned above may further includes:

a plurality of synchronous cards connected to the first type of collecting cards in an one-to-one correspondence.

A method for a grid-side harmonic test on a multiple-unit includes:

detecting analog current signals of power units of the multiple-unit;

sampling and quantifying the detected analog current signals of the power units, so as to convert the analog current signals into digital current signals, where a sampling frequency is greater than or equal to a predetermined threshold f_{T}(360/Δθ)×f₀, f_{T} denotes the predetermined threshold, Δθ denotes an error of phase angle of a harmonic component to be detected, and f₀ denotes a frequency of the harmonic component to be detected;

obtaining a whole train current signal by adding up the digital current signals; and

obtaining a harmonic component based on the whole train current signal.

Preferably, the obtaining a whole train current signal by adding up the digital current signals includes:

performing temperature compensation on the digital current signals; and

obtaining the whole train current signal by adding up the digital current signals on which the temperature compensation has been performed.

Preferably, the obtaining the whole train current signal by adding up the digital current signals on which the temperature compensation has been performed includes:

performing non-linear compensation on the digital current signals on which the temperature compensation has been performed, where a non-linear compensation value is predetermined with experiments; and

obtaining the whole train current signal by adding up the digital current signals on which the non-linear compensation has been performed.

It may be known from the technical solution that, in the system and method for the grid-side harmonic test on the multiple-unit according to the embodiments of the present disclosure, current signals of the power units are detected, the detected current signals are sampled and quantified to obtain digital current signals of the power units, the digital current signals are added up to obtain the whole train current signal, and the harmonic component is obtained based on the whole train current signal. The sampling frequency is determined based on the frequency of the harmonic component to be detected and the error of targeted phase angle of the harmonic component to be detected. With the system and method for the grid-side harmonic test on the multiple-unit according to the embodiments of the present disclosure, the accuracy of harmonic current detection can be improved and a harmonic component having a frequency above 3000 Hz can be detected.

### BRIEF DESCRIPTION OF THE DRAWINGS

The drawings to be used in the description of the embodiments or the conventional technology are described briefly as follows, such that the technical solutions according to the embodiments of the present disclosure or in the conventional technology become clearer. It is apparent that the drawings in the following description are only some embodiments of the present disclosure. For those skilled in the art, other drawings may be obtained based on these drawings without any creative work.

FIG. 1 shows a system for a grid-side harmonic test on a multiple-unit according to an embodiment of the present disclosure;

FIG. 2 is a flowchart of a method for a grid-side harmonic test on a multiple-unit according to an embodiment of the present disclosure;

FIG. 3 is a flowchart of obtaining a whole train current signal by adding up digital current signals; and

FIG. 4 is a flowchart of obtaining a whole train current signal by adding up digital current signals on which temperature compensation has been performed.

### DETAILED DESCRIPTION

The technical solution according to embodiments of the present disclosure is described clearly and completely hereafter in conjunction with drawings according to the embodiments of the present disclosure. It is apparent that the described embodiments are only a part of the embodiments of the present disclosure. All the other embodiments obtained by those skilled in the art based on the embodiments of the present disclosure without any creative work fall within the protection scope of the present disclosure.

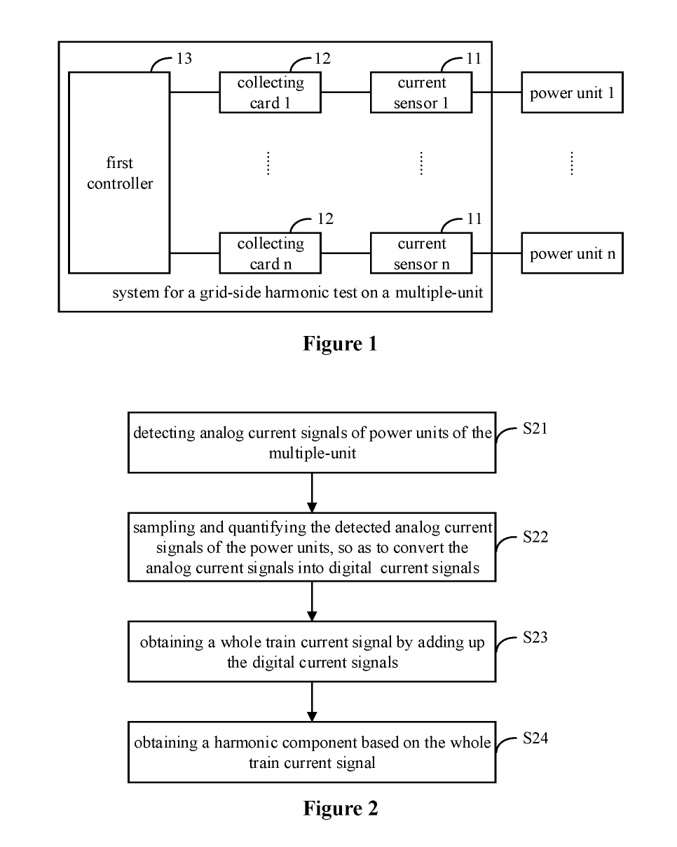

Reference is made to FIG. 1, which shows a system for a grid-side harmonic test on a multiple-unit according to an embodiment of the present disclosure.

The system may include a plurality of current sensors 11, a plurality of first type of collecting cards 12 and a first controller 13.

The current sensors 11 are connected to power units of the multiple-unit in a one-to-one correspondence. That is, each of the current sensors 11 collects a current signal of one of the power units.

Optionally, the current sensors 11 may be chosen to have an accuracy of 0.05%.

Apparently, a sensor having a higher accuracy may be chosen.

The first type of collecting cards 12 are connected to the current sensors 11 in a one-to-one correspondence. The current signals detected by the current sensors 11 are analog signals. The first type of collecting cards 12 sample and quantify the current signals detected by the current sensors 11, so as to convert the analog current signals detected by the current sensors into digital current signals. A sampling frequency of the first type of collecting cards is greater than or equal to a predetermined threshold f_{T}=(360/Δθ)×f₀, where f_{T} denotes the predetermined threshold, Δθ denotes an error of phase angle of a harmonic component to be detected, and f₀ denotes a frequency of the harmonic component to be detected.

In the embodiment of the present disclosure, the analog current signals are analog signals bearing current information of the power units, and the digital current signals are digital signals bearing current information of the power units.

The first controller 13 is connected to the plurality of the first type of collecting cards 12, and is configured to obtain a whole train current signal by adding up the digital current signals and obtain the harmonic component based on the whole train current signal.

In the embodiment of the present disclosure, current signals of the power units are detected by the current sensors 11, the detected current signals are sampled and quantified by the first type of collecting cards 12 to obtain digital current signals of the power units, the digital current signals are added up by the first controller 13 to obtain the whole train current signal, and the harmonic component is obtained based on the whole train current signal. The sampling frequency of the collecting cards is determined based on the frequency of the harmonic component to be detected and the error of targeted phase angle of the harmonic component to be detected. By testing, it is determined that the system and method for the grid-side harmonic test on the multiple-unit according to the embodiment of the present disclosure improve the accuracy of harmonic current detection and may detect a harmonic component having a frequency above 3000 Hz.

Optionally, in the above embodiment, the first controller 13, which is configured to obtain the whole train current signal by adding up the digital current signals, is configured to perform temperature compensation on the digital current signals and obtain the whole train current signal by adding up the digital current signals on which the temperature compensation has been performed.

In the embodiment, the first controller 13 first performs temperature compensation on the digital current signals upon receipt of the digital current signals and obtains the whole train current signal by adding up the digital current signals on which the temperature compensation has been performed.

Specifically, the first controller 13, which is configured to perform the temperature compensation on the digital current signals, is configured to acquire an ambient temperature in real-time, and obtain, upon receipt of the digital current signals, a variation value of the ambient temperature relative to 25 Celsius degrees and multiply the variation value by a temperature coefficient of the current sensors 11 to obtain a temperature compensation value. The temperature compensation value is added to values of the digital current signals to obtain the digital current signals on which the temperature compensation has been performed. The variation value of the ambient temperature relative to 25 Celsius degrees is a difference between the ambient temperature and 25 Celsius degrees.

In the embodiment of the present disclosure, the temperature compensation is performed on the digital current signals, which further improves the accuracy of the grid-side harmonic test on the multiple-unit.

Furthermore, the first controller 13, which is configured to obtain the whole train current signal by adding up the digital current signals on which the temperature compensation has been performed, is configured to perform non-linear compensation on the digital current signals on which the temperature compensation has been performed and obtain the whole train current signal by adding up the digital current signals on which the non-linear compensation has been performed.

In the embodiment of the present disclosure, the first controller 13 performs the non-linear compensation on the digital current signals after performing the temperature compensation on the digital current signals. That is, the digital current signals on which the temperature compensation has been performed are added to a predetermined non-linear compensation value to obtain the digital current signals on which the temperature compensation has been performed.

In the embodiment of the present disclosure, the non-linear compensation value is determined based on numerous experiments. A standard current source is mainly adopted, and a current signal outputted by the standard current source is detected by the current sensor 11 for multiple times (at least 3 times). The current signal detected by the current sensor 11 each time is compared with the current signal outputted by the standard current source to determine an error of the sensor. An average value of the errors obtained in the multiple times is calculated as the non-linear compensation value for the harmonic wave test.

In the embodiment of the present disclosure, the temperature compensation as well as the non-linear compensation are performed on the current signals, which further improves the accuracy of the grid-side harmonic test on a multiple-unit.

Optionally, in the above embodiment, the first type of collecting cards 12 may be chosen as analog-to-digital converters having a sampling frequency greater than or equal to the predetermined threshold and a conversion accuracy of 24 bits.

Optionally, in the above embodiment, the system for a grid-side harmonic test on a multiple-unit of the present disclosure may further include a plurality of synchronous cards connected to the first type of collecting cards 12 in a one-to-one correspondence.

In the embodiment of the present disclosure, the first type of collecting cards 12 obtain a clock signal by means of separate synchronous cards of a same model. The first type of collecting cards 12 operate in accordance with the IEEE-1588 clock synchronous protocol, such that the first type of collecting cards 12 perform the sampling synchronously.

In the embodiment of the present disclosure, hardware synchronization replaces software synchronization, which further improves the accuracy of the grid-side harmonic test on a multiple-unit.

Optionally, the system for a grid-side harmonic test on a multiple-unit according to an embodiment of the present disclosure may further include a plurality of voltage sensors, a plurality of second type of collecting cards and a second controller.

The plurality of voltage sensors correspond to the power units one-to-one. That is, each of the voltage sensors detects a voltage of one of the power units.

The plurality of second type of collecting cards are connected to the voltage sensors in a one-to-one correspondence, and are configured to sample and quantify analog voltage signals detected by the voltage sensors, so as to convert the analog voltage signals detected by the sensors into digital voltage signals. A sampling frequency of the second type of collecting cards is greater than or equal to a predetermined threshold f_{T}=(360/Δθ)×f₀, f_{T} denotes the predetermined threshold, Δθ denotes an error of phase angle of a harmonic component to be detected, and f₀ denotes a frequency of the harmonic component to be detected.

In the embodiment of the present disclosure, the analog voltage signals are analog signals bearing voltage information of the power units, and the digital voltage signals are digital signals bearing voltage information of the power units.

The second controller is connected to the plurality of second type of collecting cards, and is configured to obtain the digital voltage signals outputted by the voltage collecting cards and obtain the harmonic components of voltages of the power units based on the digital voltage signals outputted by the voltage collecting cards.

Furthermore, the system for a grid-side harmonic test on a multiple-unit according to an embodiment of the present disclosure may further include a storage device.

The storage device is configured to store harmonic test result data. Specifically, the storage device may include a redundant disk array.

Since the redundant disk array consists of multiple disks, the harmonic test result data may be stored in the redundant disk array in blocks. In a case that a part of the disks are damaged, data in the damaged disks may be restored based on data in disks that are not damaged, thereby reducing the possibility of losing test result data due to misoperation or disk damage.

Corresponding to the system embodiments, a method for a grid-side harmonic test on a multiple-unit is further provided in the disclosure. A flowchart of a method for a grid-side harmonic test on a multiple-unit in the present disclosure is shown in FIG. 2. The method may include steps S21 to S24.

Step S21 may include detecting analog current signals of power units of the multiple-unit.

The analog current signals of the power units of the multiple-unit may be detected by current sensors 11 having an accuracy of 0.05%.

Step S22 may include sampling and quantifying the detected analog current signals of the power units, so as to convert the analog current signals into digital current signals. A sampling frequency is greater than or equal to a predetermined threshold f_{T}=(360/Δθ)×f₀, f_{T} denotes the predetermined threshold, Δθ denotes an error of phase angle of a harmonic component to be detected, and f₀ denotes a frequency of the harmonic component to be detected.

Step S23 may include obtaining a whole train current signal by adding up the digital current signals.

Step S24 may include obtaining a harmonic component based on the whole train current signal.

In the embodiment of the present disclosure, current signals of the power units are detected, the detected current signals are sampled and quantified to obtain digital current signals of the power units, the digital current signals are added up to obtain the whole train current signal, and the harmonic component is obtained based on the whole train current signal. The sampling frequency of the collecting cards is determined based on the frequency of the harmonic component to be detected and the error of targeted phase angle of the harmonic component to be detected. By testing, it is determined that, the system and method for the grid-side harmonic test on the multiple-unit according to the embodiments of the present disclosure improve the accuracy of harmonic current detection and may detect a harmonic component having a frequency above 3000 Hz.

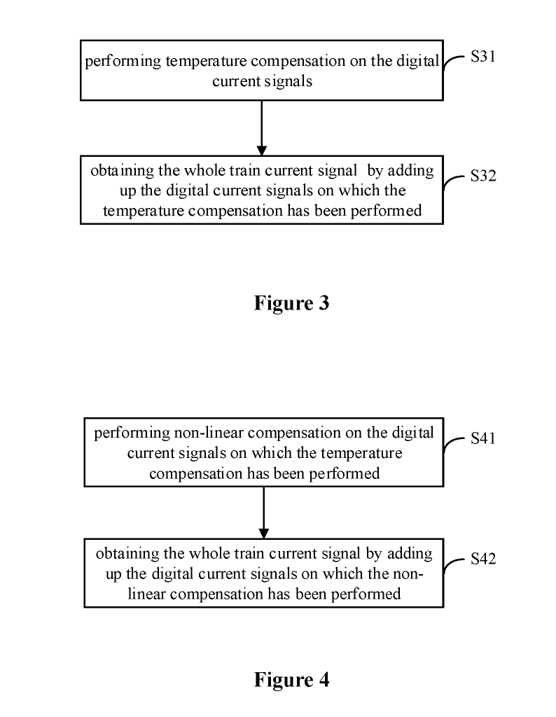

According to the above embodiment, a flowchart of obtaining a whole train current signal by adding up digital current signals is shown in FIG. 3. Optionally, step S31 and step

S32 may be included.

Step S31 may include performing temperature compensation on the digital current signals.

Specifically, an ambient temperature may be acquired in real-time, and a variation value of the ambient temperature relative to 25 Celsius degrees is obtained upon receipt of the digital current signals. The variation value is multiplied by a temperature coefficient of the current sensors 11 to obtain a temperature compensation value. The temperature compensation value is added to values of the digital current signals to obtain the digital current signals on which the temperature compensation has been performed. The variation value of the ambient temperature relative to 25 Celsius degrees is a difference between the ambient temperature and 25 Celsius degrees.

Step S32 may include obtaining the whole train current signal by adding up the digital current signals on which the temperature compensation has been performed.

In the embodiment of the present disclosure, after receipt of the digital current signals, the temperature compensation is performed on the digital current signals and then the digital current signals on which the temperature compensation has been performed are added up to obtain the whole train current signal, which further improves the accuracy of harmonic test.

According to the embodiment as shown in FIG. 3, a flowchart of obtaining a whole train current signal by adding up digital current signals on which the temperature compensation has been performed is shown in FIG. 4. Optionally, step S41 and step S42 may be included.

Step S41 may include performing non-linear compensation on the current signals on which the temperature compensation has been performed. A non-linear compensation value is predetermined with experiments.

In the embodiment of the present disclosure, the non-linear compensation value is determined based on numerous experiments. A standard current source is mainly adopted. Errors of the sensors in case of various standard current inputs are determined through checking one by one. The errors are recorded as the non-linear compensation value for the harmonic test.

Step S42 may include obtaining the whole train current signal by adding up the digital current signals on which the non-linear compensation has been performed.

In the embodiment of the present disclosure, the non-linear compensation is performed after the temperature compensation has been performed on the digital current signals. The digital current signals on which the temperature compensation has been performed are added to the predetermined non-linear compensation value to obtain the digital current signals on which the temperature compensation has been performed. In this way, the accuracy of the grid-side harmonic test on a multiple-unit is further improved.

Optionally, the method for a grid-side harmonic test on a multiple-unit according to an embodiment of the present disclosure may further include:

detecting analog voltage signals of power units of the multiple-unit;

sampling and quantifying the detected analog voltage signals, so as to convert the analog voltage signals detected by the sensors into digital voltage signals, where a sampling frequency of the second type of collecting cards is greater than or equal to a predetermined threshold f_{T}=(360/Δθ)×f₀, f_{T} denotes the predetermined threshold, Δθ denotes an error of phase angle of a harmonic component to be detected, and f₀ denotes a frequency of the harmonic component to be detected; and

obtaining digital voltage signals outputted by voltage collecting cards, and obtaining harmonic components of the voltages of the power units based on the digital voltage signals outputted by voltage collecting cards.

Furthermore, the method may further include storing the harmonic test result data. Specifically, the harmonic test result data may be stored in a redundant disk array.

Since the redundant disk array consists of multiple disks, the harmonic test result data may be stored in the redundant disk array in blocks. In a case that a part of the disks are damaged, data in the damaged disks may be restored based on data in disks that are not damaged, thereby reducing the possibility of losing test result data due to misoperation or disk damage.

It may be known by those skilled in the art that, units and algorithm steps in each example according to the embodiments can be realized by electronic hardware, computer software or a combination of the electronic hardware and computer software. Whether to execute the functions by hardware or by software depends on specific applications and design constraint conditions of the technical solution. Those skilled in the art may realize the described functions with different methods for each specific application, and the realization should not be considered beyond the scope of the disclosure.

According to the embodiments of the present disclosure, it should be understood that the disclosed system and method can be implemented in other ways. For example, the system embodiments described above are merely illustrative. For example, the units are merely divided based on logic functions, and may be divided in other ways in practice. For example, multiple devices or components may be combined, or may be integrated into another system, or some features may be ignored, or not be executed. In addition, the coupling, direct coupling or communication connection shown or discussed above may be indirect coupling or communication connection via some interfaces or devices, and may be electrical, mechanical, or in other forms.

In addition, each control device according to the embodiments of the present disclosure may be integrated into one processing unit, or may be a separate unit physically, or two or more units are integrated into one unit.

The description of the embodiments is to allow those skilled in the art to implement or use the present disclosure. Various modifications to the embodiments are apparent for those skilled in the art. The general principle defined herein can be implemented in other embodiments without departing from the essence or scope of the disclosure. Therefore, the present disclosure is not limited to the embodiments described herein, but conforms to a widest scope consistent with the principle and novel features disclosed herein.

1. A system for a grid-side harmonic test on a multiple-unit, comprising:
a plurality of current sensors, connected to power units of the multiple-unit in a one-to-one correspondence;
a plurality of first type of collecting cards, connected to the current sensors in a one-to-one correspondence, wherein the plurality of first type of collecting cards are configured to sample and quantify current signals detected by the current sensors, so as to convert analog current signals detected by the current sensors into digital current signals, a sampling frequency of the first type of collecting cards is greater than or equal to a predetermined threshold f_{T}=(360/Δθ)×f₀, f_{T} denotes the predetermined threshold, Δθ denotes an error of phase angle of a harmonic component to be detected, and f₀ denotes a frequency of the harmonic component to be detected; and
a first controller, connected to the plurality of first type of collecting cards, and configured to obtain a whole train current signal by adding up the digital current signals and to obtain the harmonic component based on the whole train current signal.

2. The system according to claim 1, wherein the current sensors have an accuracy of 0.05%.

3. The system according to claim 1, wherein the first controller, which is configured to obtain the whole train current signal by adding up the digital current signals, is configured to:
perform temperature compensation on the digital current signals and obtain the whole train current signal by adding up the digital current signals on which the temperature compensation has been performed.

4. The system according to claim 3, wherein the first controller, which is configured to obtain the whole train current signal by adding up the digital current signals on which the temperature compensation has been performed, is configured to:
perform non-linear compensation on the digital current signals on which the temperature compensation has been performed, and obtain the whole train current signal by adding up the digital current signals on which the non-linear compensation has been performed, wherein a non-linear compensation value is predetermined with experiments.

5. The system according to claim 1, wherein the first type of collecting cards are analog-to-digital converters having a sampling frequency greater than or equal to the predetermined threshold and a conversion accuracy of 24 bits.

6. The system according to claim 1, further comprising:
a plurality of synchronous cards connected to the first type of collecting cards in an one-to-one correspondence.

7. A method for a grid-side harmonic test on a multiple-unit, comprising:
detecting analog current signals of power units of the multiple-unit;
sampling and quantifying the detected analog current signals of the power units, so as to convert the analog current signals into digital current signal signals, wherein a sampling frequency is greater than or equal to a predetermined threshold f_{T}=(360/Δθ)×f₀, f_{T} denotes the predetermined threshold, Δθ denotes an error of phase angle of a harmonic component to be detected, and f₀ denotes a frequency of the harmonic component to be detected;
obtaining a whole train current signal by adding up the digital current signals; and
obtaining a harmonic component based on the whole train current signal.

8. The method according to claim 7, wherein the obtaining a whole train current signal by adding up the digital current signals comprises:
performing temperature compensation on the digital current signals; and
obtaining the whole train current signal by adding up the digital current signals on which the temperature compensation has been performed.

9. The method according to claim 8, wherein the obtaining the whole train current signal by adding up the digital current signals on which the temperature compensation has been performed comprises:
performing non-linear compensation on the current signals on which the temperature compensation has been performed, wherein a non-linear compensation value is predetermined with experiments; and
obtaining the whole train current signal by adding up the digital current signals on which the non-linear compensation has been performed.

10. The system according to claim 2, further comprising:
a plurality of synchronous cards connected to the first type of collecting cards in an one-to-one correspondence.

11. The system according to claim 3, further comprising:
a plurality of synchronous cards connected to the first type of collecting cards in an one-to-one correspondence.

12. The system according to claim 4, further comprising:
a plurality of synchronous cards connected to the first type of collecting cards in an one-to-one correspondence.

13. The system according to claim 5, further comprising:
a plurality of synchronous cards connected to the first type of collecting cards in an one-to-one correspondence.
